(19) United States
(12) Patent Application Publication
(10) Pub. No.: US 2024/0274549 A1
(43) Pub. Date: Aug. 15, 2024

(54) SUBSTRATE DEFINED COUPLED INDUCTORS WITH EMBEDDED SOLID FERRITE CORE

(71) Applicants: Advanced Micro Devices, Inc., Santa Clara, CA (US); ATI Technologies ULC, Markham (CA)

(72) Inventors: Alexander Helmut Pfeiffenberger, Markham (CA); Robert Grant Spurney, Austin, TX (US); Sriranga Sai Boyapati, Austin, TX (US)

(21) Appl. No.: 18/169,788

(22) Filed: Feb. 15, 2023

(51) Int. Cl. H01L 23/64; H01F 17/00; H01F 17/04; H01L 23/14; H01L 23/498; H01L 25/065

(52) U.S. Cl. CPC H01L 23/645; H01F 17/0013; H01F 17/04; H01L 23/145; H01L 23/49822; H01L 23/49838; H01L 25/0655; H01F 2017/002; H01L 24/16; H01L 24/32; H01L 24/73; H01L 2224/16227; H01L 2224/16237; H01L 2224/32225; H01L 2224/73204; H01L 2924/1427; H01L 2924/1432; H01L 2924/1433; H01L 2924/14335

(57) ABSTRACT

An apparatus and method for efficient power management of multiple integrated circuits. An apparatus includes an integrated circuit and a package substrate that includes an embedded inductor. The package substrate includes a glass-reinforced epoxy laminate material. The embedded inductor is formed within a cavity of the package substrate, and includes two negatively coupled inductors connected in a parallel combination. The embedded inductor receives an output voltage generated by a voltage regulator, and conveys this output voltage to a power supply input pin of the integrated circuit. Each of the two negatively coupled inductors utilizes a ferrite core. During a transient voltage condition of the output voltage generated by the voltage regulator, the embedded inductor provides an inductance that is less than an inductance it provides for a steady-state voltage condition of the output voltage generated by the voltage regulator.

### BACKGROUND

### Description of the Relevant Art

There is a growing demand for semiconductor packages that provide communication between one or more integrated circuits in a chip package and external components on a motherboard located externally from the chip package. The design of servers used in high-performance computing (HPC) and datacenter applications continue to attempt to reduce power consumption while simultaneously increasing performance. These designs of the servers require more current to be delivered from voltage regulators on a printed circuit board (PCB) to the package substrate and silicon die through socket pins or ball-grid arrays (BGAs). This current delivery is used by control interconnect signals, data interconnect signals, and power reference level interconnect signals throughout the system.

The demand for increased performance also increases the demand for semiconductor package substrates (or package substrates). The package substrate is a part of the chip package that provides mechanical base support as well as provides an electrical interface for the signal interconnects. In some designs, vertical through silicon vias (TSVs) are formed in the silicon package substrate that has connections to the printed circuit board using bump pads. In other designs, vertical through mold vias (TMVs) are formed in a substrate made of mold compounds that include organic resins (epoxy resin), non-melting inorganic filler (fused silica), catalysts, and so forth. Groups of TSVs or TMVs forming buses through a corresponding substrate are used as interconnects between a base die, one or more additional integrated circuits, and routing on a printed circuit board (PCB) such as a motherboard or a card.

When transferring information between a transmitter and a receiver, typically, electrical signals are sent on multiple, parallel metal traces. Transmitters send the electrical signals across the parallel metal traces. Receivers receive the electrical signals. The metal traces have transmission line effects such as distributed inductance, capacitance, and resistance throughout its length. For modern integrated circuits, the interconnect capacitance reduces signal integrity and signal transfer rate more so than gate capacitance of semiconductor devices. The interconnect capacitance per unit length includes both sidewall fringing capacitance and cross-coupling capacitance. For example, the electromagnetic fields for the metal traces conducting signals and the return current on the ground plane create electrical interference on neighboring metal traces and on adjacent devices. In addition to signals that transport control information, source data information, and intermediate and result data information, there are signals that transport power supply reference levels. Power management schemes typically use multiple different power supply voltages (power supply reference levels) to provide configurable operating parameters to portions of integrated circuits.

Designers provide multiple signal integrity components within or nearby the metal signal routes to reduce the distortion caused by the many sources of noise (transmission line effects). These components typically include passive elements arranged in a particular manner to prevent the source of noise from affecting the shape and amplitude of the electrical signals being sent across the metal signal routes. Examples of the passive elements are resistors, inductors, and capacitors. As the number of voltage regulators increase to provide multiple power supply reference levels to the integrated circuit die(s) within a semiconductor chip, the number of large inductors used to stabilize the multiple power supply reference levels also increase. These inductors are typically large. Placing these inductors on the side of the silicon package substrate where the integrated circuits are located does not allow the inductors to be fully utilized for noise reduction. In addition, the inductors consume a large amount of area on the silicon package substrate, which reduces the density of signal routes.

In view of the above, efficient methods and systems for creating power supply inductors for semiconductor chip packages are desired.

### BRIEF DESCRIPTION OF THE DRAWINGS

FIG. 1 is a generalized block diagram of an embedded voltage regulating inductor.

FIG. 2 is a generalized block diagram of a timing diagram of response times of voltage regulator inductors.

FIG. 3 is a generalized block diagram of an embedded voltage regulating inductor.

FIG. 4 is a generalized block diagram of a semiconductor chip package.

FIG. 5 is a generalized block diagram of an embedded voltage regulating inductor.

FIG. 6 is a generalized block diagram of an embedded voltage regulating inductor.

FIG. 7 is a generalized block diagram of an embedded voltage regulating inductor.

FIG. 8 is a generalized block diagram of a method for creating power supply inductors for semiconductor chip packages.

FIG. 9 is a generalized block diagram of a method for creating power supply inductors for semiconductor chip packages.

FIG. 10 is a generalized block diagram of a computing system.

While the invention is susceptible to various modifications and alternative forms, specific implementations are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### DETAILED DESCRIPTION

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention. Further, it will be appreciated that for simplicity and clarity of illustration, elements shown in the figures have not necessarily been drawn to scale. For example, the dimensions of some of the elements are exaggerated relative to other elements.

Apparatuses and methods efficiently transferring information as signals through a silicon package substrate are contemplated. An apparatus includes an integrated circuit; and a package substrate that includes an embedded inductor. In some implementations, the package substrate includes a glass-reinforced epoxy laminate material. The embedded inductor is formed within a cavity of the package substrate, and includes two negatively coupled inductors connected in a parallel combination. The embedded inductor receives an output voltage generated by a voltage regulator, and conveys this output voltage to a power supply input pin of the integrated circuit. Each of the two negatively coupled inductors utilizes a ferrite core.

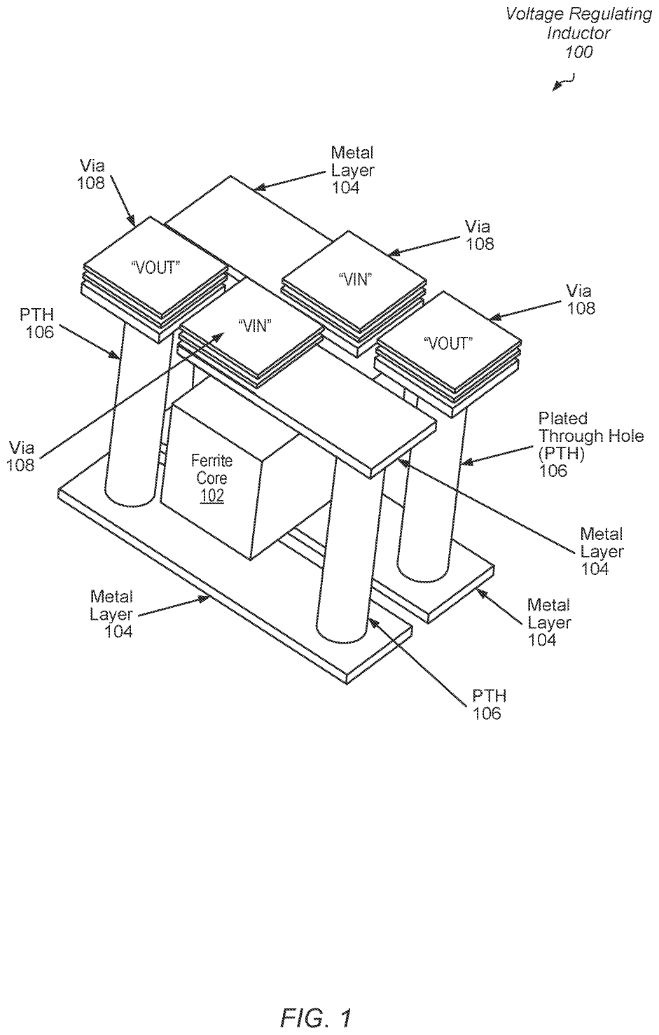

During a transient voltage condition of the output voltage generated by the voltage regulator, the embedded inductor provides a first inductance less than a second inductance provided by the embedded inductor for a steady-state voltage condition of the output voltage generated by the voltage regulator. In some implementations, each of the two negatively coupled inductors comprises at least two windings of a metal coil around the ferrite core. In an implementation, a metal coil of at least one of the two negatively coupled inductors is oriented in a diagonal direction relative to the ferrite core. The embedded inductor formed by these two negatively coupled ferrite core inductors provides a high inductance during the steady-state conditions. This embedded inductor also provides a low inductance during the transient conditions. The negative coupling between the two ferrite core inductors also provides ripple current cancellation. Further details are provided in the following description of FIGS. 1-10.

Referring to FIG. 1, a generalized block diagram is shown of an embedded voltage regulating inductor 100. As shown, the embedded voltage regulating inductor 100 (or inductor 100) includes a ferrite core 102 with two metal coils wound around it using the metal layer 104 and plated through-holes (PTHs) 106. Vias 108 provide connections between the metal coils and external voltage pins. In various implementations, the vias 108 marked “VIN” are electrically connected to an output of a voltage regulator (not shown), and the vias 108 marked “VOUT” are electrically connected to a power supply voltage input pin of an integrated circuit. Therefore, the inductor 100 is used as a passive component that provides a stable power supply voltage (or power supply reference level) to the integrated circuit.

The combination of the voltage regulator and the inductor 100 provides a voltage regulating power supply voltage (or power supply reference level) to the die of the integrated circuit. The inductor 100 provides energy storage, and the voltage regulator provides control of the energy storage such as regulating the build-up of energy in the inductor 100 and the discharge of the energy from the inductor 100 to the power distribution network of the die of the integrated circuit. The voltage regulator includes one or more of a power switch that includes one or more transistors, one or more comparators, a pulse width modulator (PWM), and a digital-to-analog converter (DAC). The inductor 100 allows the power supply voltage to resist voltage droop during operation of the integrated circuit, reduce current ripple on the power supply voltage input pin, and provide a quick voltage ramp up during a power-on sequence. In various implementations, the voltage regulator is placed on top of the package substrate similar to the die of the integrated circuit, whereas, the inductor 100 is embedded in the package substrate. For example, the inductor 100 is formed in a core layer of a package substrate. Similar to the motherboard and other printed circuit boards, such as expansion cards, network cards, and video cards, the core layer utilizes a glass-reinforced epoxy laminate material. Therefore, the inductor 100 is an embedded passive component within the core layer of the package substrate. The package substrate also includes multiple layers of dielectric (not shown) including dielectric surrounding the inductor 100.

The inductor 100 includes two negatively coupled ferrite core inductors combined in a parallel manner. The inductor on the left includes a metal coil that is wound (or wrapped) in a clockwise direction from the node marked “VIN” to the node marked “VOUT.” The inductor on the right includes a metal coil that is wound (or wrapped) in a counterclockwise direction from the node marked “VIN” to the node marked “VOUT.” In other implementations, the winding (or wrapping) is in the other direction for each of the two metal coils such that they remain wound in opposite directions from one another. Although not shown for ease of illustration, it is possible and contemplated that the bottom side of the package substrate below the bottom of the inductor 100 is placed on multiple interconnects of a motherboard. The other side of the package substrate above the top of the inductor 100 has one or more integrated circuits placed on top of it.

Although the orientation of the inductor 100 is shown to have vias 108 at the top and the PTHs 106 are routed in a vertical direction, other orientations are possible and contemplated. It is understood that a silicon wafer, an integrated circuit, and a core layer of a package substrate can be rotated and flipped. Therefore, the materials and layers being described would be rotated and flipped, and the orientations and directions would have a different meaning. Therefore, the terms “top,” “bottom,” “horizontal,” “vertical,” “left,” “right,” “clockwise,” “counterclockwise,” “above,” and “below” can change as the inductor 100 is rotated or flipped, and the use of these terms in the below description correspond to the orientation being shown in the inductor 100.

The two ferrite core inductors are connected between the nodes “VIN” and “VOUT” in a parallel manner. Current flowing through the windings (or wrappings) of the two metal coils in opposite directions (clockwise and counterclockwise) provide the negative coupling and the resulting mutual inductance. For example, in one implementation, when the left ferrite core inductor and the right ferrite core inductor are negatively coupled with one another, the current of the left ferrite core inductor flows in a clockwise direction and the current of the right ferrite core inductor flows in a counterclockwise direction. In another implementation, the current of the left ferrite core inductor flows in a counterclockwise direction and the current of the right ferrite core inductor flows in a clockwise direction.

The mutual inductance provided by the negative coupling reduces the self-inductance of each of the two ferrite core inductors, since the resulting mutual inductance is negative based on the polarity of the mutual voltage in reference to the direction of the inducing current. For example, the induced voltage, V1, of the left ferrite core inductor is L1×(di1/dt)−M×(di2/dt). In this equation, L1 is the self-inductance of the left ferrite core inductor, i1 is the current flowing through the left ferrite core inductor from the node “VIN” to the node “VOUT”, M is the mutual inductance provided by the right ferrite core inductor, and i2 is the current flowing through the right ferrite core inductor from the node “VIN” to the node “VOUT.” The induced voltage, V2, of the right ferrite core inductor is L2×(di2/dt)−Mx (di1/dt). In this equation, L2 is the self-inductance of the right ferrite core inductor.

The two negatively coupled ferrite core inductors combined in a parallel manner share a high permeability core such as the ferrite core 102. The ferrite core 102 includes a high permeability material on top of a dielectric layer between the ferrite core 102 and the metal layer 104. For example, the high permeability material includes an alloy that contains at least the metal Iron (Fe). Therefore, the high permeability material is a ferrous material (or a ferrite material). Examples of the high-permeability material is an alloy that includes Iron (Fe) with one of Nickel (Ni), Chromium (Cr), Cobalt (Co), Molybdenum (Mo), Vanadium (V), and Manganese (Mn). The general chemical composition of the ferrite material is XFe2O4 where the symbol X represents one of the multiple choices for the transition metal that is combined with Iron.

Using the ferrite material as the ferrite core 102 of the inductor 100, rather than an air core, improves the quality factor of the inductor 100. The ferrite core 102 also increases the self-inductance of the inductor 100. The ferrite core 102 of the inductor 100 is more efficient at storing magnetic energy than an air core inductor with a same number of wraps or turns of the metal coil. Accordingly, the ferrite core 102 additionally reduces the required number of turns of the coils and allows more space between turns of the coils of the inductor 100 for a same amount of self-inductance when compared to an air core inductor. Although the ferrite core 102 of the inductor 100 increases the magnitude of the self-inductance, the ferrite material contributes high core loss at high frequencies. Therefore, the inductor 100 with the ferrite core 102 is used in circuit applications requiring high power levels and low signal frequencies. Accompanying a power supply reference level from a voltage regulator is one example of such a circuit application.

Combined with the metal layer 104, the PTHs 106 form signal routes on either side of the ferrite core 102. There is a metal layer 104 both above and below the ferrite core 102. However, the top metal layer 104 does not have physical connections such as the gaps between the nodes “VIN” and “VOUT” above the ferrite core 102. In various implementations, the metal layer 104 includes copper or an alloy of other metals, such as aluminum, mixed with copper. As described earlier, the two metal coils around the ferrite core 102 form two signal routes in opposing directions (clockwise on the left versus counterclockwise on the right). These two different coils form two ferrite core inductors that are both in a parallel combination with respect to one another and negatively coupled with one another.

The equivalent inductor, which is inductor 100, formed by these two negatively coupled ferrite core inductors provides a high inductance during steady-state conditions. This equivalent inductor 100 also provides a low inductance during transient conditions due to the negative coupling. The negative coupling of the two ferrite core inductors also provides ripple current cancellation. In addition to the number of turns or wrappings of the metal coils and the spacings between the wrappings, the dimensions of the embedded ferrous material used to form the ferrite core 102, the vias 108, and the metal traces formed in the metal layer 104 are tuned to provide the desired inductive reactance and resistance at an operating frequency of a corresponding voltage regulator.

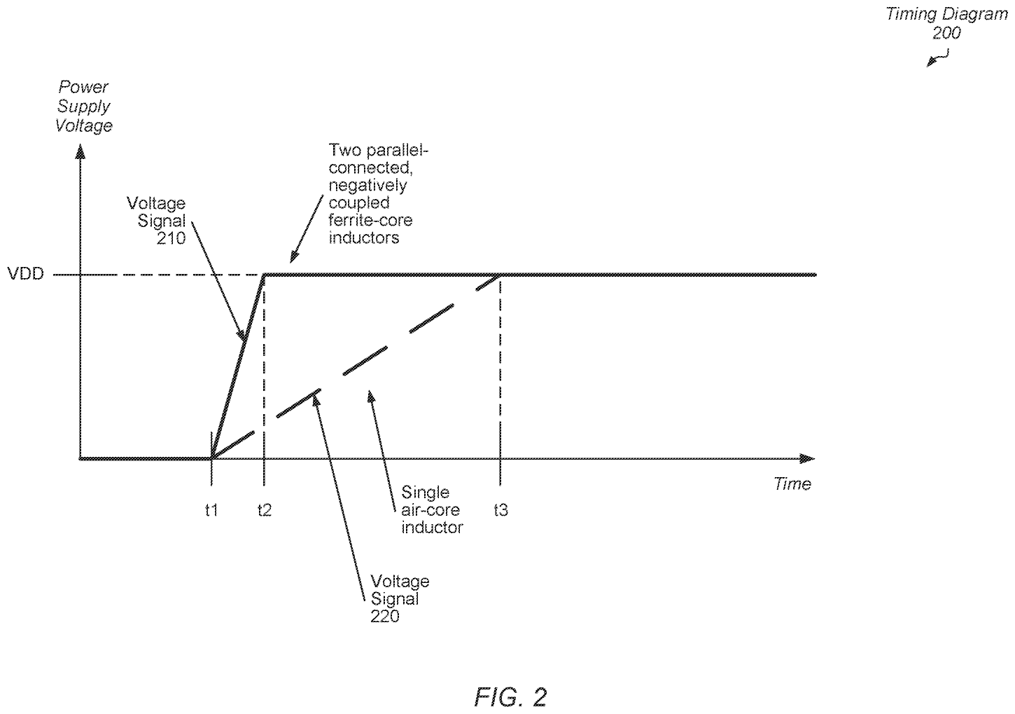

Referring now to FIG. 2, a generalized block diagram is shown of a timing diagram 200 of response times of voltage regulator inductors. The timing diagram 200 illustrates a voltage signal 210 and a voltage signal 220 over time. The voltage signal 210 is a voltage output from an embedded inductor that includes two negatively coupled ferrite core inductors in a parallel combination. The embedded inductor is placed within a package substrate. In various implementations, the embedded inductor has the materials and circuit topology of voltage regulating inductor 100 (of FIG. 1). In contrast, the voltage signal 220 is a voltage output from an air-core inductor with no negative coupling. This air-core inductor can be placed on top of the package substrate between a voltage regulator and a die of an integrated circuit. Alternatively, this air-core inductor can be placed within the package substrate. It is noted that while the signals are illustrated as being linear in FIG. 2, this need not be the case. In various implementations, the signals may at time be linear or non-linear.

As shown, the response time for the voltage signal 210 is faster than the response time of the voltage signal 220. The voltage signal 210 is able to ramp up from a first voltage level, such as zero volts, to a second voltage level, such as a power supply voltage of “VDD,” between the point in time t1 (or time t1) and the time t2. Other examples of the first voltage level and the second voltage level are possible and contemplated. In an implementation, a voltage regulator is powered up, or otherwise, receives an indication to change its voltage output, at time t1. When the embedded inductor is placed in series between the output of the voltage regulator and the power supply voltage input pin of an integrated circuit, the voltage input pin receives the voltage signal 210. When another inductor, such as an air-core inductor placed on top of the package substrate, is placed in series between the output of the voltage regulator and the power supply voltage input pin of the integrated circuit, the voltage input pin receives the voltage signal 220.

In some implementations, the response time between times t1 and t2 of the voltage signal 210 is in the range of a dozen nanoseconds. An inductor, such as the above embedded inductor, provides fast and lossless integrated circuit (IC) power supply voltage changes, which reduces power consumption and increases performance. In contrast, the voltage signal 220 requires the duration of time between the time t1 and the time t3 to ramp up from the first voltage level to the second voltage level. By doing so, any inductor used between the output of the voltage regulator and the power supply voltage input pin of the integrated circuit delays a transition to a next operating state in addition to consuming more power. An inductor, such as the above embedded inductor, formed by two negatively coupled ferrite core inductors in a parallel combination provides a high inductance during steady-state conditions such as from time t2 and on. This inductor also provides a low inductance during transient conditions such as between time t1 and time t2.

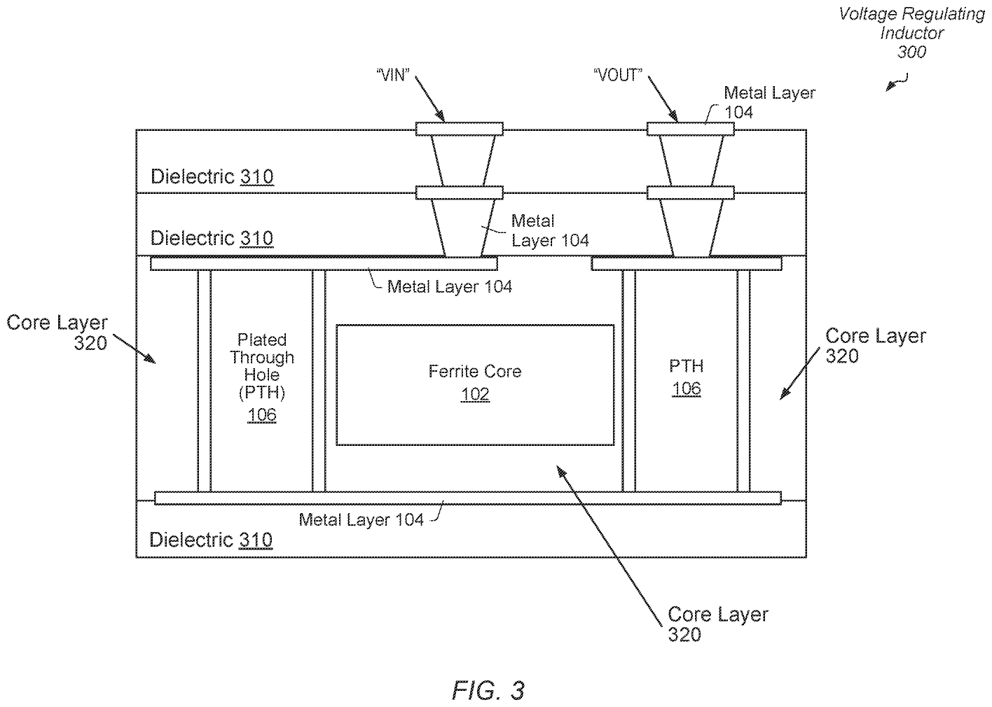

Referring to FIG. 3, a generalized block diagram is shown of an embedded voltage regulating inductor 300. Materials, layers, and components previously described are numbered identically. Similar to the embedded voltage regulating inductor 100, the embedded inductor 300 includes two negatively coupled ferrite core inductors in a parallel combination. The embedded voltage regulating inductor 300 of FIG. 3 provides a cross-section view of the inductor 100 (of FIG. 1). The metal layer 104 and the PTH 106 form a metal coil around the ferrite core 102. A dielectric 310 is deposited above and below the core layer 320 of the package substrate. In some implementations, the PTHs 106 are formed in the core layer 320 by using lasers. In other implementations, the PTHs 106 are formed in the core layer 320 by mechanical drilling. The ferrite core 102 is formed within the core layer 320 of a package substrate after a cavity is formed in the core layer 320.

In various implementations, the vias 108 marked “VIN” are electrically connected to an output of a voltage regulator, and the vias 108 marked “VOUT” are electrically connected to a power supply voltage input pin of an integrated circuit. Similar to the motherboard and other printed circuit boards, such as expansion cards, network cards, and video cards, the core layer 320 utilizes a glass-reinforced epoxy laminate material. This material provides relatively high mechanical strength while also providing electrical insulation between interconnects and semiconductor chips.

One example of the glass-reinforced epoxy laminate material is the FR-4 (or FR4) glass epoxy. Another example is a glass bismaleimide triazine (BT) epoxy. The core layer 320 includes one or more signal routes that are embedded in the FR-4 material and run through the FR-4 material. Although a single metal coil is shown in the inductor 300, a second metal coil is formed either behind the shown metal coil (looking into the page), or the second metal coil is formed in front of the shown metal coil (coming out of the page). The second metal coil winds around the ferrite core 102 in a different direction than the shown metal coil. Therefore, the two inductors formed by the two metal coils are negatively coupled.

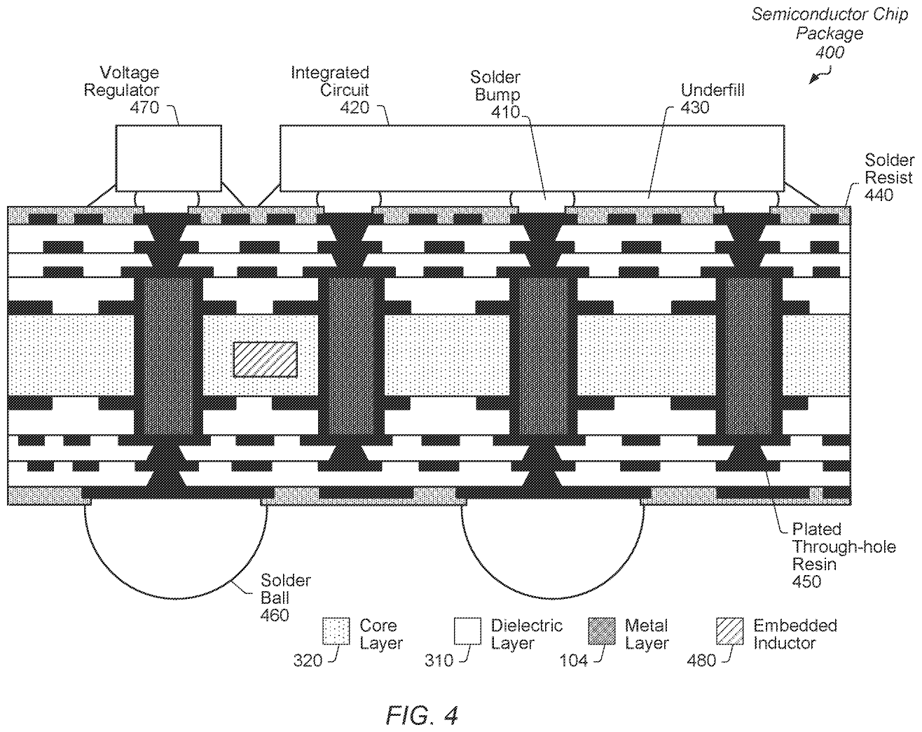

FIG. 4 illustrates a generalized block diagram of a semiconductor chip package 400. Materials, layers, and components previously described are numbered identically. As shown, the semiconductor chip package 400 (or chip package 400) uses a variety of types of interconnects. One example are the controlled collapse chip connection (C4) interconnections 410, which are also referred to as flip-chip interconnection. Another example are the solder balls 460. The solder balls 460 provide a connection between the multiple layers of the package substrate and the motherboard (not shown). The solder resist 440 is an insulating ink that covers the surface of printed wiring boards and protects the circuit pattern. The underfill 430 is a composite material made up of an epoxy polymer that is used to compensate for thermal expansion of materials between the integrated circuit (IC) 420 and the package substrate. The package substrate uses plated through-holes (PTHs) with a corresponding resin 450.

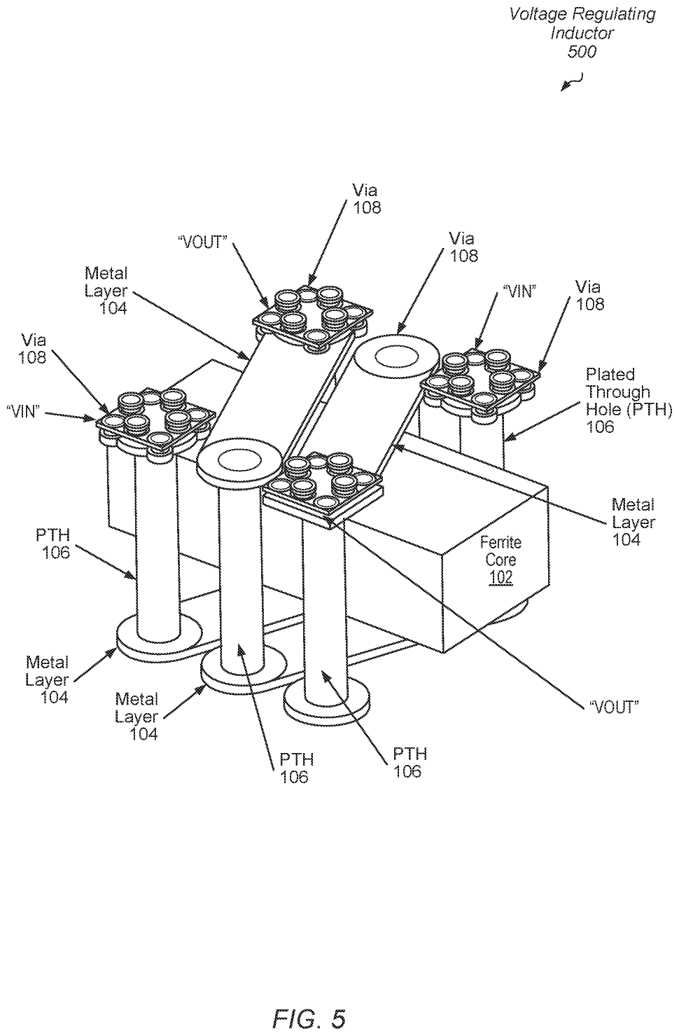

The integrated circuit 420 can be one of a variety of types of an integrated circuit. Examples of the integrated circuit 420 are a central processing unit (CPU), a digital signal processor (DSP), a graphics processing unit (GPU), an application specific integrated circuit (ASIC), a field programmable gate array (FPGA), a multimedia engine, and so forth. Any number of power supply reference levels are generated by the voltage regulator 470 for use by circuitry within the integrated circuit 420. In various implementations, the embedded inductor 480 includes the materials, layers, and connectivity of the inductors 100, and 300 (of FIGS. 1 and 3), and inductors 500-700 (of upcoming FIGS. 5-7).

A voltage output signal from the voltage regulator 470 is routed to a power supply voltage input pin of the integrated circuit 420 through the embedded inductor 480. Signal routes using the metal layer 104 in the dielectric layers 310 and the core layer 320 are used to route the power supply reference level from the voltage regulator 470 to the integrated circuit 420 through the embedded inductor 480. The embedded inductor 480 formed by two negatively coupled ferrite core inductors in a parallel combination provides a high inductance during steady-state conditions. This embedded inductor 480 also provides a low inductance during transient conditions, and thus, fast response times. The negative coupling between the two separate ferrite core inductors of the embedded inductor 480 also provides ripple current cancellation.

Turning now to FIG. 5, a generalized block diagram is shown of an embedded voltage regulating inductor 500. Materials, layers, and components previously described are numbered identically. Similar to the embedded voltage regulating inductor 100, the embedded inductor 500 includes two negatively coupled ferrite core inductors in a parallel combination. In various implementations, the vias 108 marked “VIN” are electrically connected to an output of a voltage regulator, and the vias 108 marked “VOUT” are electrically connected to a power supply voltage input pin of an integrated circuit. Therefore, the inductor 500 is used as a passive component that provides a stable power supply voltage (or power supply reference level) to the integrated circuit.

In contrast to the embedded voltage regulating inductor 100 (or inductor 100), the embedded voltage regulating inductor 500 (or inductor 500), includes metal traces provided by the metal layer 104 used in metal coils that are routed in a diagonal direction relative to the ferrite core 102, rather than routed in a direction perpendicular to the longitude of the ferrite core 102 as provided by the inductor 100. For example, the inductor 500 includes metal traces provided by the metal layer 104 used in metal coils that are routed at an angle different from 90 degrees relative to the ferrite core 102. The metal traces provided by the metal layer 104 used in metal coils of the inductor 500 are routed at an angle of 45 degrees, 30 degrees, or other angle relative to the longitude of the ferrite core 102.

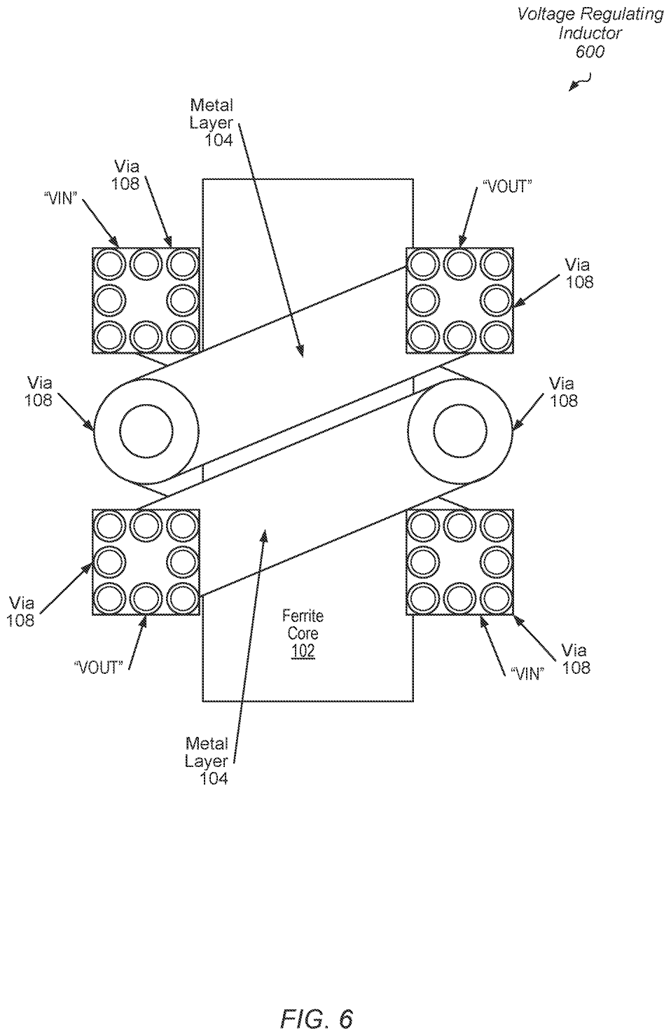

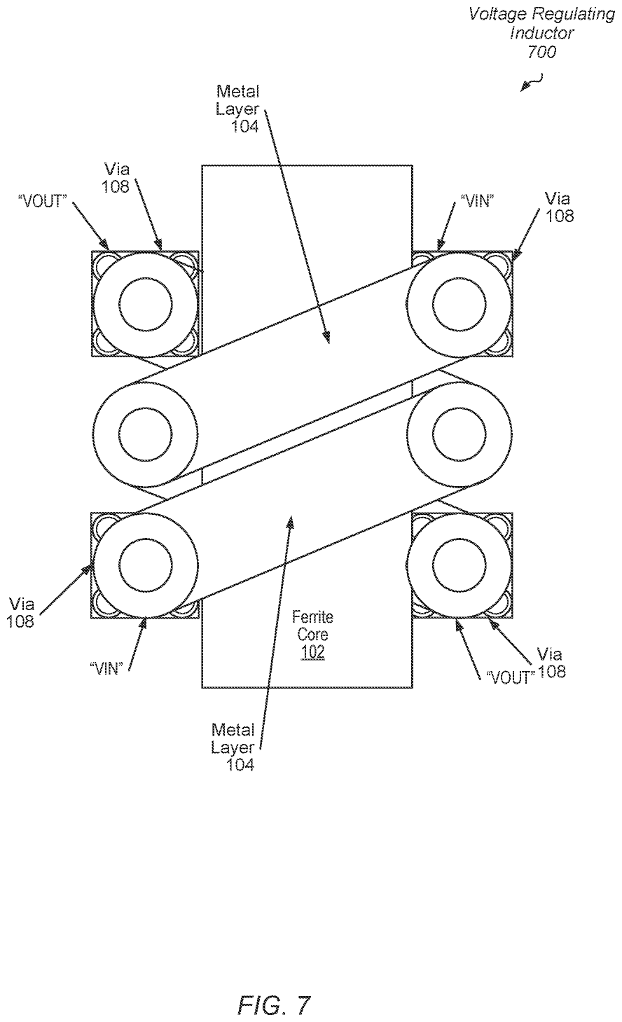

The inductor 500 provides two turns (or two wraps) of the metal coils implemented with the metal layers 104 and the PTHs 106, rather than a single turn (or a single wrap). Two turns of the metal coils provide a higher inductance, but also a higher resistance. The tradeoff between inductance and resistance is based on the measured response times, and the dimensions used for the metal traces provided by the metal layer 104, the PTHs 106, and the vias 108. The embedded voltage regulating inductor 600 of FIG. 6 provides a top view of the inductor 500. The embedded voltage regulating inductor 700 of FIG. 7 provides a bottom view of the inductor 500. For each of the inductors 600 and 700, materials, layers, and components previously described are numbered identically.

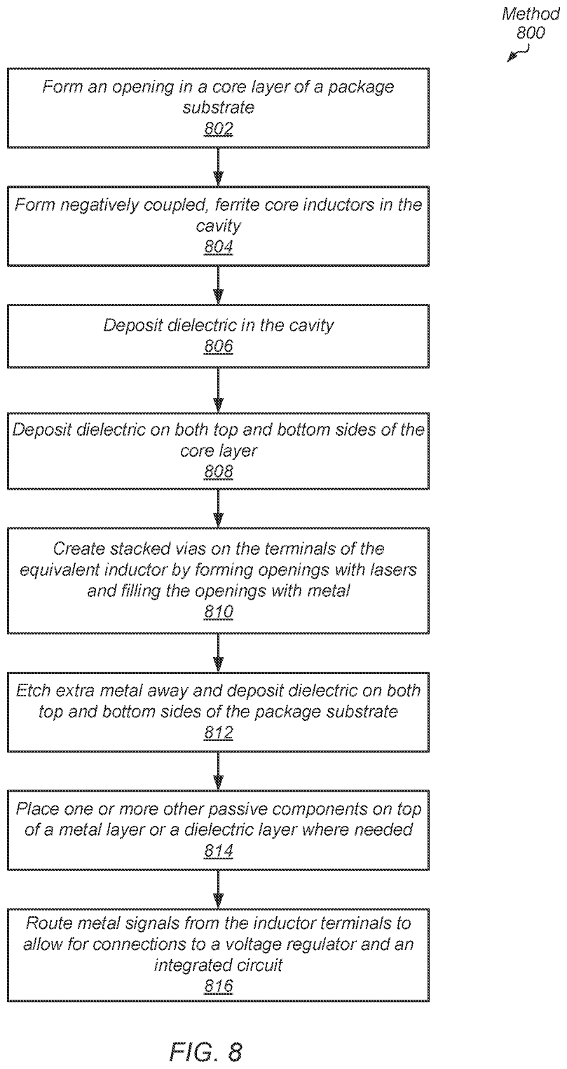

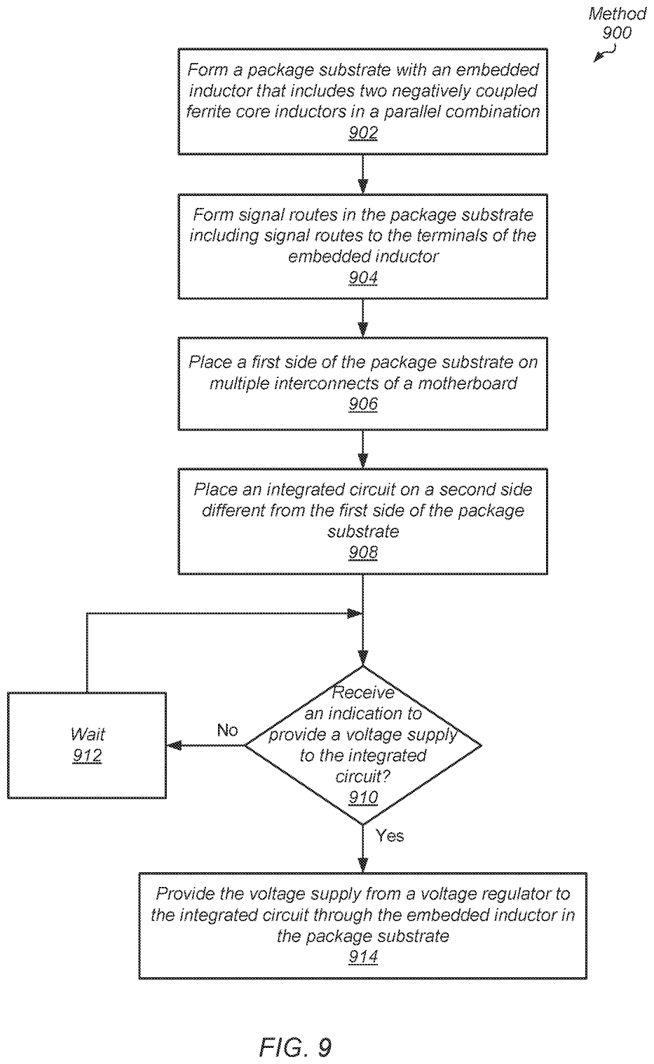

Referring now to FIG. 8, a generalized block diagram is shown of a method 800 for creating power supply inductors for semiconductor chip packages. For purposes of discussion, the steps in this implementation (as well as in FIG. 9) are shown in sequential order. However, in other implementations some steps occur in a different order than shown, some steps are performed concurrently, some steps are combined with other steps, and some steps are absent.

A semiconductor fabrication process (or process) forms an opening in a substrate core layer of a package substrate (block 802). In some implementations, the process uses lasers to create the opening. The process forms negatively coupled ferrite core inductors in the cavity (block 804). To do so, the process places a metal layer at the bottom of the opening followed by depositing dielectric on top of the metal layer. Afterward, the process deposits a high permeability material on top of the dielectric. For example, the high permeability material includes an alloy that contains at least the metal Iron (Fe). Therefore, the high permeability material is a ferrous material (or a ferrite material). Examples of the high-permeability material is an alloy that includes Iron (Fe) with one of Nickel (Ni), Chromium (Cr), Cobalt (Co), Molybdenum (Mo), Vanadium (V), and Manganese (Mn). The general chemical composition of the ferrite material is XFe₂O₄ where the symbol X represents one of the multiple choices for the transition metal that is combined with Iron.

Using the ferrite material as the ferrite core of the inductor, rather than an air core, improves the quality factor of the inductor. The ferrite core also increases the self-inductance of the inductor. The ferrite core inductor is more efficient at storing magnetic energy than an air core inductor with a same number of wraps or turns of the metal coil. Accordingly, the ferrite core additionally reduces the required number of turns of the coils and allows more space between turns of the coils of the inductor for a same amount of self-inductance when compared to an air core inductor. Although a ferrite core inductor increases the magnitude of the self-inductance, the ferrite material contributes high core loss at high frequencies. Therefore, the ferrite core inductor is used in circuit applications requiring high power levels and low signal frequencies. Accompanying a power supply reference level from a voltage regulator is one example of such a circuit application.

The process deposits a dielectric over the ferrite core of the inductor, and forms signal routes such as plated through-holes (PTHs) in the substrate core layer on either side of the ferrite core. The process forms a metal layer on top of the dielectric that goes over the PTHs, but does not connect the PTHs to one another. When forming this top metal layer and the earlier bottom metal layer, the process can use a route aligned with the ferrite core, or form metal layers in a diagonal direction relative to the ferrite core. The processor forms two metal coils around the ferrite core with the two metal coils wound (or wrapped) around the ferrite core in two different directions. These two different coils form two ferrite core inductors that are both in a parallel combination with respect to one another and negatively coupled with one another.

The equivalent inductor formed by these two negatively coupled ferrite core inductors provides a high inductance during steady-state conditions. This equivalent inductor also provides a low inductance during transient conditions. The negative coupling between the ferrite core inductors also provides ripple current cancellation. In addition to the number of turns or wrappings of the metal coils and the spacings between the wrappings, the dimensions of the embedded ferrous material, the vias, and the metal traces used to form the metal coils of the two negatively coupled ferrite core inductors are tuned to provide the desired inductive reactance and resistance at an operating frequency of a corresponding voltage regulator.

The process deposits dielectric in the cavity (block 806). The process deposits dielectric on both top and bottom sides of the core layer (block 808). By forming openings with lasers and filling the openings with metal, the process creates stacked vias on the PTHs used to provide terminals of the equivalent inductor formed by the two negatively coupled ferrite core inductors (block 810). The process etches extra metal away and deposit dielectric on both top and bottom sides of the package substrate (block 812). The process places one or more other passive components on top of a metal layer or a dielectric layer where needed (block 814). The process routes metal signals from the inductor terminals through the package substrate to allow for connections to a voltage regulator and an integrated circuit (block 816). The package substrate is ready to be placed in a chip package.

Referring to FIG. 9, a generalized block diagram is shown of a method 900 for creating power supply inductors for semiconductor chip packages. A semiconductor fabrication process (or process) forms a package substrate with an embedded inductor that includes two negatively coupled ferrite core inductors in a parallel combination (block 902). The process forms signal routes in the package substrate including signal routes to the terminals of the embedded inductor (block 904). In various implementations, the embedded inductor includes the materials, layers, and connectivity of the inductors 100, 300, and 500-700 (of FIGS. 1, 3 and 5-7).

The process places a first side of the package substrate on multiple interconnects of a motherboard (block 906). The process places an integrated circuit on a second side different from the first side of the package substrate (block 908). The process completes the connections of the chip package, which can be one of a ball grid array (BGA) surface mount package, a chip scale package (CSP), or a System in Package (SiP). A potential, such as at least one power supply voltage, is applied to one or more nodes of the chip package in addition to components on the motherboard. A voltage regulator receives the power supply voltage, and is capable of generating another power supply voltage based on the received power supply voltage.

If the voltage regulator does not receive the potential, and thus, does not receive an indication to provide a voltage supply to the integrated circuit (“no” branch of the conditional block 910), then the package substrate waits for the potential to be applied (block 912). However, if the package substrate receives the potential, and thus, does receive an indication to provide a voltage supply to the integrated circuit (“yes” branch of the conditional block 910), then the voltage regulator provides the voltage supply to the integrated circuit through the embedded inductor in the package substrate (block 914). The embedded inductor formed by the two negatively coupled ferrite core inductors in a parallel combination provides a high inductance during steady-state conditions. This embedded inductor also provides a low inductance during transient conditions. The negative coupling between the two separate ferrite core inductors also provides ripple current cancellation.

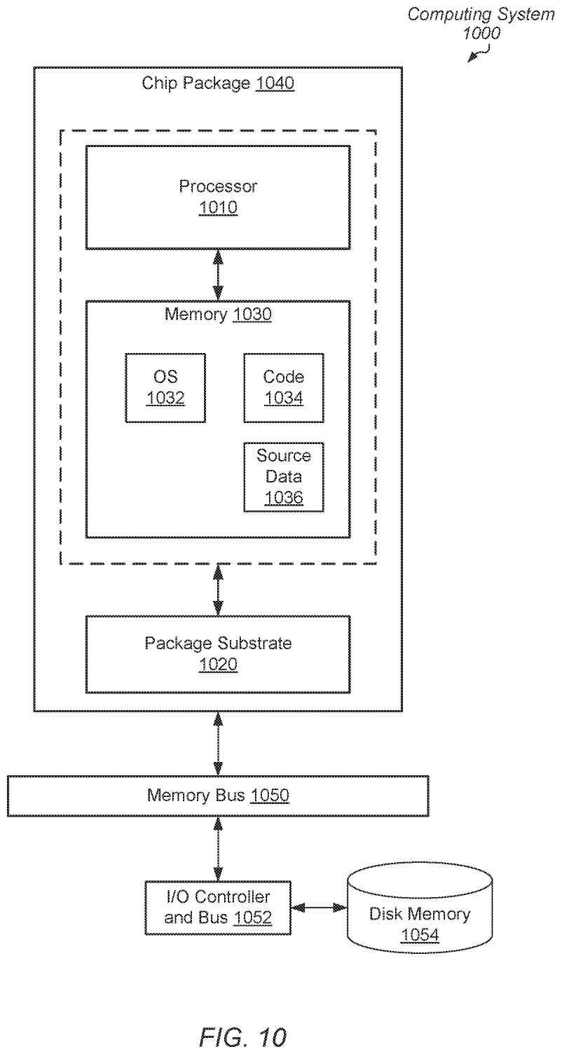

Referring to FIG. 10, one implementation of a computing system 1000 is shown that utilizes multiple embedded passive components located in multiple layers of a package substrate. The computing system 1000 utilizes a chip package 1040, which includes the package substrate 1020. The package substrate 1020 includes one or more embedded inductors, each including two negatively coupled ferrite core inductors in a parallel combination. In various implementations, the package substrate 1020 includes the materials, layers, and components of the inductors 100, 300, and 500-700 (of FIGS. 1, 3 and 5-7). The chip package 1040 uses one of a ball grid array (BGA) surface mount package, a chip scale package (CSP), and a System in Package (SiP). The chip package 1040 communicates with other components on a motherboard (or printed circuit board). In an implementation, the computing system 1000 includes the processor 1010 and the memory 1030 in the chip package 1040.

In another implementation, only one of the processor 1010 and the memory 1030 is included in the chip package 1040. Although a single processor is shown, in other implementations, the chip package 1040 includes another number of processors and a variety of other types of integrated circuits (ICs). The number and type of ICs located in the chip package 1040 is based on design requirements. Interfaces, such as a memory controller, a bus, or a communication fabric, one or more phased locked loops (PLLs) and other clock generation circuitry, a power management unit, and so forth, are not shown for ease of illustration. Additionally, in the illustrated implementation, the chip package 1040 is connected to the disk memory 1054 through the memory bus 1050 and the input/output (I/O) controller and bus 1052.

It is understood that in other implementations, the computing system 1000 includes one or more peripheral devices, a network interface, one or more other memory devices, and so forth. In some implementations, the functionality of the computing system 1000 is incorporated on a system on chip (SoC). In other implementations, the functionality of the computing system 1000 is incorporated on a peripheral card inserted in a motherboard. The computing system 1000 is used in any of a variety of computing devices such as a desktop computer, a server computer, a tablet computer, a laptop, a smartphone, a smartwatch, a gaming console, a personal assistant device, and so forth.

The processor 1010 includes hardware such as circuitry. In various implementations, the processor 1010 includes one or more processing units. In some implementations, each of the processing units includes one or more processor cores capable of general-purpose data processing, and an associated cache memory subsystem. In such an implementation, the processor 1010 is a central processing unit (CPU). In another implementation, the processing cores are compute units, each with a highly parallel data microarchitecture with multiple parallel execution lanes and an associated data storage buffer. In such an implementation, the processor 1010 is a graphics processing unit (GPU), a digital signal processor (DSP), or other.

In some implementations, the memory 1030 includes one of a variety of types of dynamic random-access memories (DRAMs). The memory 1030 stores at least a portion of an operating system (OS) 1032, one or more applications represented by code 1034, and at least source data 1036. In various implementations, the memory 1030 stores a copy of these software components 1032, 1034 and 1036 that have original copies stored on disk memory 1054. Memory 1030 is also capable of storing intermediate result data and final result data generated by the processor 1010 when executing a particular application of code 1034.

In various implementations, the off-chip disk memory 1054 includes one or more hard disk drives (HDDs) and Solid-State Disks (SSDs) comprising banks of Flash memory. The I/O controller and bus 1052 supports communication protocols with the off-chip disk memory 1054. Although a single operating system 1032 and a single instance of code 1034 and source data 1036 are shown, in other implementations, another number of these software components are stored in memory 1030 and disk memory 1054. The operating system 1032 includes instructions for initiating the boot up of the processor 1010, assigning tasks to hardware circuitry, managing resources of the computing system 1000 and hosting one or more virtual environments.

It is noted that one or more of the above-described implementations include software. In such implementations, the program instructions that implement the methods and/or mechanisms are conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium includes any storage media accessible by a computer during use to provide instructions and/or data to the computer. For example, a computer accessible storage medium includes storage media such as magnetic or optical media, e.g., disk (fixed or removable), tape, CD-ROM, or DVD-ROM, CD-R, CD-RW, DVD-R, DVD-RW, or Blu-Ray. Storage media further includes volatile or non-volatile memory media such as RAM (e.g., synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g., Flash memory) accessible via a peripheral interface such as the Universal Serial Bus (USB) interface, etc. Storage media includes microelectromechanical systems (MEMS), as well as storage media accessible via a communication medium such as a network and/or a wireless link.

Additionally, in various implementations, program instructions include behavioral-level descriptions or register-transfer level (RTL) descriptions of the hardware functionality in a high level programming language such as C, or a design language (HDL) such as Verilog, VHDL, or database format such as GDS II stream format (GDSII). In some cases, the description is read by a synthesis tool, which synthesizes the description to produce a netlist including a list of gates from a synthesis library. The netlist includes a set of gates, which also represent the functionality of the hardware including the system. The netlist is then placed and routed to produce a data set describing geometric shapes to be applied to masks. The masks are then used in various semiconductor fabrication steps to produce a semiconductor circuit or circuits corresponding to the system. Alternatively, the instructions on the computer accessible storage medium are the netlist (with or without the synthesis library) or the data set, as desired. Additionally, the instructions are utilized for purposes of emulation by a hardware based type emulator from such vendors as Cadence®, EVER, and Mentor Graphics®.

Although the implementations above have been described in considerable detail, numerous variations and modifications will become apparent to those skilled in the art once the above disclosure is fully appreciated. It is intended that the following claims be interpreted to embrace all such variations and modifications.

What is claimed is:

1. An apparatus comprising:
a package substrate comprising an embedded inductor that includes two negatively coupled inductors connected in a parallel combination, wherein the embedded inductor is configured to:
generate an output voltage signal based on a given voltage signal; and
convey the output voltage signal.

2. The apparatus as recited in claim 1, wherein each of the two negatively coupled inductors utilizes a ferrite core.

3. The apparatus as recited in claim 2, wherein the apparatus further comprises an integrated circuit, wherein:
the given voltage signal is a power supply reference level generated by a voltage regulator; and
the embedded inductor conveys the output voltage signal to the integrated circuit.

4. The apparatus as recited in claim 2, wherein responsive to a transient voltage condition of the given voltage signal, the embedded inductor is configured to provide a first inductance, wherein the first inductance is less than a second inductance provided by the embedded inductor for a steady-state voltage condition of the given voltage signal.

5. The apparatus as recited in claim 2, wherein each of the two negatively coupled inductors comprises at least two windings of a metal coil around the ferrite core.

6. The apparatus as recited in claim 5, wherein a metal coil of at least one of the two negatively coupled inductors is oriented in a diagonal direction relative to the ferrite core.

7. The apparatus as recited in claim 2, wherein the package substrate comprises a glass-reinforced epoxy laminate material.

8. A method, comprising:
receiving, by an embedded inductor, a given voltage signal, wherein the embedded inductor includes two negatively coupled inductors connected in a parallel combination; and
conveying, by the embedded inductor, an output voltage signal based on the given voltage signal.

9. The method as recited in claim 8, further comprising conveying, by the embedded inductor, the output voltage signal utilizing a ferrite core by each of the two negatively coupled inductors.

10. The method as recited in claim 9, further comprising receiving, by the embedded inductor, the given voltage signal as a power supply reference level generated by a voltage regulator.

11. The method as recited in claim 9, wherein responsive to a transient voltage condition of the given voltage signal, the method further comprises providing, by the embedded inductor, a first inductance less than a second inductance provided by the embedded inductor for a steady-state voltage condition of the given voltage signal.

12. The method as recited in claim 9, further comprising conveying the output voltage signal by the embedded inductor utilizing at least two windings of a metal coil around the ferrite core for each of the two negatively coupled inductors.

13. The method as recited in claim 12, further comprising conveying the output voltage signal by the embedded inductor utilizing a metal coil of at least one of the two negatively coupled inductors oriented in a diagonal direction relative to the ferrite core.

14. The method as recited in claim 9, further comprising conveying the output voltage signal by the embedded inductor located within a package substrate comprising a glass-reinforced epoxy laminate material.

15. A computing system comprising:
a chip package comprising:
an integrated circuit; and
a package substrate comprising an embedded inductor that includes two negatively coupled inductors connected in a parallel combination, wherein the embedded inductor is configured to:
generate an output voltage signal based on a given voltage signal; and
convey the output voltage signal to the integrated circuit.

16. The computing system as recited in claim 15, wherein each of the two negatively coupled inductors utilizes a ferrite core.

17. The computing system as recited in claim 16, wherein the given voltage signal is a power supply reference level generated by a voltage regulator.

18. The computing system as recited in claim 16, wherein responsive to a transient voltage condition of the given voltage signal, the embedded inductor provides a first inductance less than a second inductance provided by the embedded inductor for a steady-state voltage condition of the given voltage signal.

19. The computing system as recited in claim 16, each of the two negatively coupled inductors comprises at least two windings of a metal coil around the ferrite core.

20. The computing system as recited in claim 19, wherein a metal coil of at least one of the two negatively coupled inductors is oriented in a diagonal direction relative to the ferrite core.
